(19) United States
(12) Patent Application Publication
(10) Pub. No.: US 2026/0267044 A1
(43) Pub. Date: Sep. 10, 2026

(54) METHOD OF FABRICATING AN OPTICAL STRUCTURE

(71) Applicant: Applied Materials, Inc., Santa Clara, CA (US)

(72) Inventors: Wenhui WANG, San Jose, CA (US); Lei JIANG, San Ramon, CA (US); Yongan XU, Santa Clara, CA (US); Zefang WANG, Santa Clara, CA (US)

(21) Appl. No.: 19/489,172

(22) PCT Filed: May 23, 2024
(86) PCT No.: PCT/US2024/030732

§ 371 Date: Dec. 1, 2025

Related U.S. Application Data
(60) Provisional application No. 63/506,150, filed on Jun. 5, 2023.

(51) Int. Cl. G02B 5/18; G03F 7/00; G03F 7/40

(52) U.S. Cl. CPC G02B 5/1857; G03F 7/0005; G03F 7/40

(57) ABSTRACT

Aspects of the present disclosure provide methods of fabricating an optical structure. An example method includes obtaining a first optical structure having a substrate and a nanoscale structure layer disposed above the substrate, wherein the nanoscale structure layer comprises a plurality of nanoscale structures. The method further includes applying a photoresist coating that covers at least a first Fabricate an Optical Structure nanoscale structure and a second nanoscale structure among the plurality of nanoscale structures without covering at least a third nanoscale structure among the plurality of nanoscale structures. The method further includes reducing at least one dimension of the third nanoscale structure to form a second optical structure

### BACKGROUND

### Field

Aspects of the present disclosure relate to optical devices, and more particularly, to a method of fabricating an optical structure, such as a photonic metasurface.

### Description of the Related Art

Flat optics are optical elements which are relatively thin and may not have curved surfaces like those of typical lenses. Examples of flat optics include optical windows, filter plates, thin-film polarizers, and diffractive optical elements. Some flat optics may be realized through photonic metasurfaces, which may include surfaces that have nanoscale (sub-wavelength) structures. Photonic metasurfaces can enable flexible and effective regulation of electromagnetic wave characteristics such as polarization, amplitude, phase, polarization mode, and propagation mode. In some cases, the photonic metasurfaces may have a sub-wavelength thickness. As an example, a photonic metasurface having a stepped grating can improve the diffraction efficiency as the number of phase quantization levels increases across the surface. A similar improvement in diffraction efficiency can be achieved with a binary structure as the number of duty cycle levels increases across the surface. As the number of levels for the steps or duty cycles increases for the metasurface, the dimension associated with the narrowest trench, narrowest nanoscale structure, or shortest step can become challenging to fabricate.

Accordingly, what is needed in the art is an improved method of fabricating photonic metasurfaces.

### SUMMARY

Some aspects provide a method of fabricating an optical structure. The method includes obtaining a first optical structure having a substrate and a nanoscale structure layer disposed above the substrate, wherein the nanoscale structure layer comprises a plurality of nanoscale structures. The method further includes applying a photoresist coating that covers at least a first nanoscale structure and a second nanoscale structure among the plurality of nanoscale structures without covering at least a third nanoscale structure among the plurality of nanoscale structures. The method further includes reducing at least one dimension of the third nanoscale structure to form a second optical structure.

Some aspects provide a method of fabricating an optical structure. The method includes obtaining a first optical structure having a substrate and a nanoscale structure layer disposed above the substrate, wherein the nanoscale structure layer comprises a plurality of nanoscale structures. The method further includes applying a photoresist coating that covers at least a first nanoscale structure and a second nanoscale structure among the plurality of nanoscale structures without covering at least a third nanoscale structure among the plurality of nanoscale structures, wherein the photoresist coating comprises a single body that coats at least the first nanoscale structure and the second nanoscale structure. The method further includes reducing at least one dimension of the third nanoscale structure to form a second optical structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and may admit to other equally effective embodiments.

FIGS. 1A and 1B illustrate an example optical structure having multiple levels of duty cycles and steps among nanoscale structures.

FIG. 2 is a diagram illustrating example stages for fabricating an optical structure.

FIG. 3 is a diagram illustrating example stages for fabricating an optical structure using a segmented photoresist.

FIG. 4 is a diagram illustrating example stages for fabricating an optical structure using an isotropic etching process.

FIG. 5 is a diagram illustrating example stages for fabricating an optical structure using a hardmask disposed above the nanoscale structures.

FIGS. 6A and 6B are cross-sectional views of example beginning optical structures and ending optical structures associated with the methods of fabricating an optical structure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects of the present disclosure provide methods of fabricating an optical structure, for example, including a photonic metasurface.

Flat optics can be used for various optical elements including, for example, optical windows, filter plates, thin-film polarizers, and diffractive optical elements. Some of the flat optics may use a photonic metasurface, which may include a surface that has nanoscale (sub-wavelength) structures, such as pillars or fins having sub-wavelength dimensions. In some cases, the nanoscale structures (e.g., pillars, lines, fins, or steps) may have varying levels of duty cycles or steps (e.g., varying heights) arranged across the metasurface. To achieve some of these varying levels across the metasurface, negative tone development (NTD) processes or positive tone development (PTD) processes may be performed. For example, an NTD process may enable the formation of small trenches between adjacent pillars (or fins), and a PTD process may enable the formation of narrow pillars (or fins).

However, there can be some challenges in forming some nanoscale structures, such as a structure with narrow trenches (e.g., a trench width or diameter of less than 70 nm) and narrow pillars (e.g., a pillar width or diameter of less than 70 nm). In some aspects, the width of a structure may correspond to a diameter of such a structure, or vice versa. For example, if an NTD process is used to facilitate the formation of a narrow trench between some of the adjacent pillars, the narrowest pillar (or line or fin) may have a size that is larger than certain design specifications (e.g., >70 nm). Performing an etch shrink to reduce the width of pillars may not be available as such a process may alter the narrow trenches achieved with the NTD process. In some cases, the NTD process may be incapable of forming some of the narrowest pillars (e.g., <70 nm). For example, in a flat optic having seven levels of different duty cycles in a binary nanoscale structure, the NTD process may be incapable of forming the two narrowest pillars. As a result, the flat optic may be effectively formed with five levels of different duty cycles and a large gap where the two narrowest pillars would be arranged. Further, the flat optic may be capable of achieving a diffraction efficiency (e.g., 90%) associated with five levels of duty cycles instead of the expected design target (e.g., >90% diffraction efficiency) associated with the seven levels of duty cycles.

Aspects of the present disclosure provide methods of fabricating an optical structure, such as a photonic metasurface. As an example, the fabrication process may selectively cover some of the nanoscale structures (e.g., pillars, lines, fins, etc.) with a photoresist coating and adjust a dimension (e.g., a width and/or height) associated with the uncovered nanoscale structures, for example, via a plasma etching process (anisotropic and/or isotropic). The photoresist coating may be trimmed to uncover additional nanoscale structure(s), and an etching process may again be performed to adjust a dimension associated with the uncovered nanoscale structures. Such a process may enable a step-like structure to be formed among a binary structure having levels of duty cycles. In some aspects, the optical structure may have a combination of step-like structures and binary structures to achieve improved optical performance, for example, a diffraction efficiency greater than 90%.

The methods of fabrication described herein may provide various advantages. For example, the method described herein can facilitate the fabrication of nanoscale structures having reduced dimensions, for example, less than 70 nm. Such reduced dimensions can facilitate an increased number of levels associated with duty cycles and/or steps across the nanoscale structures, such as seven or greater levels of duty cycles and/or steps. The seven or greater levels of duty cycles and/or steps may enable improved performance of an optical element having such nanoscale structures, such as an improved diffraction efficiency (>90%).

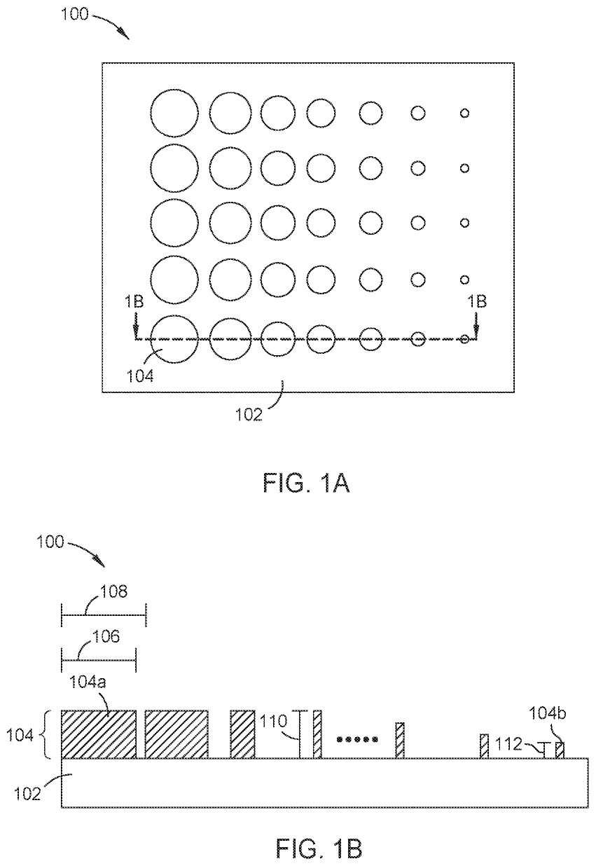

FIGS. 1A and 1B illustrate an example optical structure 100 having multiple levels of duty cycles and steps among nanoscale structures. FIG. 1A illustrates a top view of the optical structure, and FIG. 1B illustrates a cross-sectional view along line A-A as depicted in FIG. 1A. The optical structure 100 may include a substrate 102 and a plurality of nanoscale structures 104. The substrate 102 may be or include a photonic material, such as Fused silica, silicon, silicon oxide (SiOₓ), glass, or any combination thereof. The substrate 102 may be or include a transparent or semi-transparent crystal material, such as silicon carbide (SiC), sapphire, etc. In some cases, the substrate may be or include noble metals, non-noble metals, oxides, ceramics, phase change materials, semiconductors, or any combination thereof. In some cases, the substrate 102 may be configured as a waveguide having an output coupler and/or input coupler (not shown) optically coupled to the nanoscale structures 104.

In this example, the nanoscale structures 104 may be or include (cylindrical) pillars that extend from the substrate 102 as depicted in FIG. 1B. The nanoscale structures 104 may be arranged above the substrate 102. The nanoscale structures 104 may include a photonic material, such as silica glass, silicon, silicon oxide (SiOₓ), glass, or any combination thereof. The nanoscale structures 104 may be or include transparent or semi-transparent crystal material, such as silicon carbide (SiC), sapphire, etc. In some cases, the nanoscale structures 104 may include noble metals, non-noble metals, oxides, ceramics, phase change materials, semiconductors, or any combination thereof, for example. In certain cases, the nanoscale structures 104 may have a refractive index that is the same as or different from the substrate 102.

As shown, the nanoscale structures 104 may be arranged in a binary pattern, such as a square wave pattern having different duty cycles across the nanoscale structures 104. The duty cycle may represent the ratio of the width 106 of a nanoscale structure 104 to the width 108 of the period of the binary pattern. For example, the duty cycle associated with a first nanoscale structure 104a may be about 90%, whereas the duty cycle associated with a second nanoscale structure 104 b may be about 10%. The duty cycles may gradually increase within a sequence of the nanoscale structures 104 (for example, the sequence of seven nanoscale structures depicted in FIG. 1B), and the duty cycle pattern may be repeated across adjacent sequences as depicted in FIG. 1A. In certain cases, adjacent nanoscale structures 104 in the sequence may have the same duty cycle. In this example, the first nanoscale structure 104 may be representative of the nanoscale structure at one end (e.g., the beginning or first) of the sequence of nanoscale structures, and the second nanoscale structure may be representative of the nanoscale structure at the opposite end (e.g., the last or final) of the sequence of nanoscale structures.

In certain aspects, the nanoscale structures 104 may be arranged in a stepped pattern having a range of different heights for the nanoscale structures 104. For example, the first nanoscale structure 104a may have a first height 110, whereas the second nanoscale structure 104b may have a second height 112 that is less than the first height 110. The heights of the nanoscale structures 104 may gradually increase within a sequence of the nanoscale structures 104 (for example, the sequence of seven nanoscale structures depicted in FIG. 1B), and the stepped or graded heights may be repeated across adjacent sequences. In certain cases, adjacent nanoscale structures 104 in the sequence may have the same height, for example, as depicted in FIG. 1B.

The photonic pillars depicted in FIGS. 1A and 1B are examples of a photonic metasurface. Aspects of the present disclosure may be applied to fabricating any suitable photonic metasurface having nanoscale structures, for example, including pillars, gratings (e.g., blazed grating, slanted gratings, binary gratings, etc.), lines, fins, etc.

It will be appreciated that the seven levels of duty cycles and/or steps within a sequence of nanoscale structures as shown in FIGS. 1A and 1B is an example. Aspects of the present disclosure may be applied to any number of levels of duty cycles and/or steps in a sequence of nanoscale structures, such as optical structures having greater than seven levels of duty cycles and/or steps.

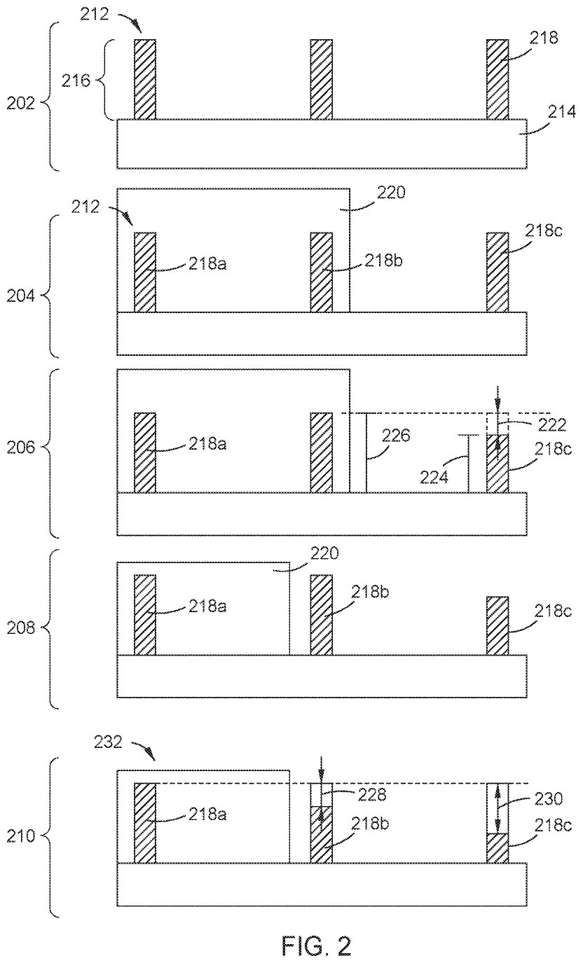

FIG. 2 is a diagram illustrating example stages 202-210 for fabricating an optical structure 232. At stage 202, a first optical structure 212 may be obtained. The first optical structure 212 may have substrate 214 (e.g., the substrate 102) and a nanoscale structure layer 216 disposed above the substrate 214. The nanoscale structure layer 216 may include a plurality of nanoscale structures (e.g., the nanoscale structures 104), for example, as described herein with respect to FIGS. 1A and 1B. The nanoscale structures 218 may be arranged in a binary pattern having varying duty cycles, for example, as described herein with respect to FIGS. 1A and 1B, and the following stages 204-210 described herein may be performed to adjust the heights of the nanoscale structures 218. For example, the binary pattern may be formed using an NTD process providing narrow trenches (e.g., gaps less than 50 nm between adjacent nanoscale structures).

At stage 204, a photoresist coating 220 may be applied to the first optical structure 212. The photoresist coating 220 may include a single body of photoresist that covers at least a first nanoscale structure 218a (e.g., a pillar) and a second nanoscale structure 218b among the nanoscale structures 218 without covering at least a third nanoscale structure 218c. The single body of photoresist may cover some of the nanoscale structures in a sequence of nanoscale structures. In certain cases, the third nanoscale structure 218c may be the last or final nanoscale structure in a sequence of nanoscale structures, for example, the nanoscale structure 104b.

At stage 206, a dimension (e.g., a height) of the third nanoscale structure 218c may be reduced. An etching process (e.g., a wet etching process and/or dry etching process) may be used to selectively remove a portion of the third nanoscale structure 218c. For example, an anisotropic plasma etching process may be performed to etch at a first depth 222, such that the third nanoscale structure 218c has a reduced height 224 compared to the heights 226 of the first nanoscale structure 218a and the second nanoscale structure 218b. The photoresist coating 220 may prevent the first nanoscale structure 218a (e.g., a pillar) and the second nanoscale structure 218b from being affected by the etching process.

At stage 208, the photoresist coating 220 may be trimmed to uncover the second nanoscale structure 218b. For example, the trimmed photoresist coating 220 may cover at least the first nanoscale structure 218a without covering the second nanoscale structure and the third nanoscale structure.

At stage 210, a dimension of the second nanoscale structure 218b and the third nanoscale structure 218c may be reduced. An etching process may be used to selective remove a portion of the second nanoscale structure 218b and the third nanoscale structure 218c. For example, an anisotropic plasma etching process may be performed to etch at a second depth 228, which may result in a third depth 230 for the third nanoscale structure 218c. The second nanoscale structure 218b has a reduced height compared to the height of the first nanoscale structure 218a, and the third nanoscale structure 218c has a reduced height compared to the height of the first nanoscale structure 218a and the second nanoscale structure 218b. The etching of the second nanoscale structure 218b and the third nanoscale structure 218c may form a second nanoscale structure 232 arranged in a binary pattern having levels (e.g., seven levels or more) of varying duty cycles and/or steps across a sequence of nanoscale structures as described herein with respect to FIGS. 1A and 1B.

In certain aspects, stages 208 and 210 may be repeated to form additional levels across a sequence of nanoscale structures (e.g., subsequent nanoscale structures in the corresponding sequence). For example, for a seven level sequence, the trimming of the photoresist coating and etching may be performed to yield up to seven different heights among the nanoscale structures in the sequence. In some cases, some of the adjacent nanoscale structures (e.g., pairs, triplets, and so forth) may be uncovered at the same time such that the adjacent nanoscale structures yield the same height.

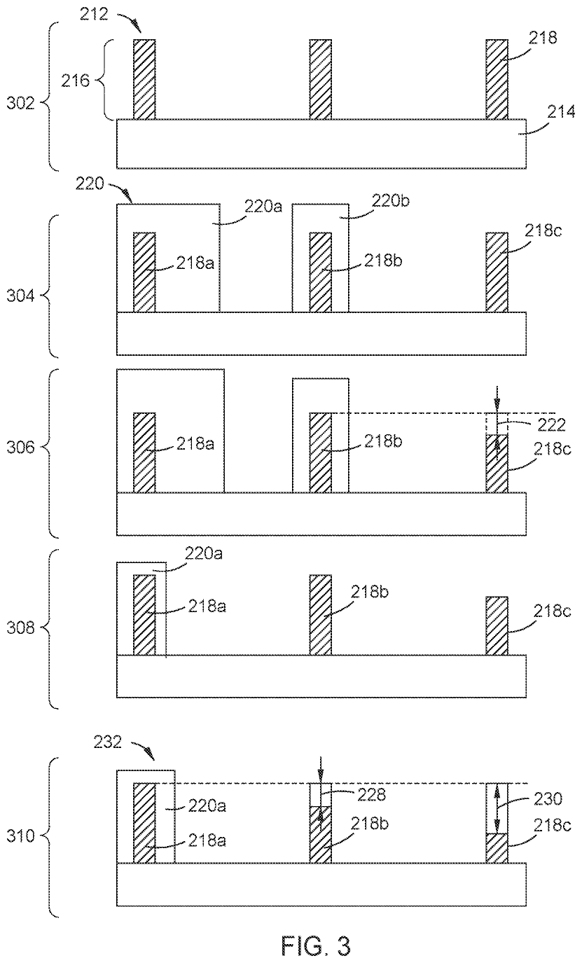

FIG. 3 is a diagram illustrating example stages 302-310 for fabricating an optical structure 232 using a segmented photoresist. The same stages and/or similar stages may be performed as described herein with respect to FIG. 2. In this example, a segmented photoresist may be used in addition to or instead of the single body of photoresist. For example, at stage 304, a photoresist coating 220 may be applied to the first optical structure 212. The photoresist coating 220 includes a first segment 220a and a second segment 220b, where the first segment 220a is separated or detached from the second segment 220b. The first segment 220a may cover the first nanoscale structure 218a, and the second segment 220b may cover the second nanoscale structure 218b. The photoresist coating 220 may be patterned to form the first segment 220a and the second segment 220b. At stage 308, the photoresist coating may be trimmed to remove the second segment 220b that covers the second nanoscale structure 218b.

Aspects of the present disclosure for fabricating the optical structure may use a combination of a single body of photoresist coating (e.g., the body covering multiple nanoscale structures) as described herein with respect to FIG. 2 and a segmented photoresist coating (e.g., each segment covering a single nanoscale structure) as described herein with respect to FIG. 3.

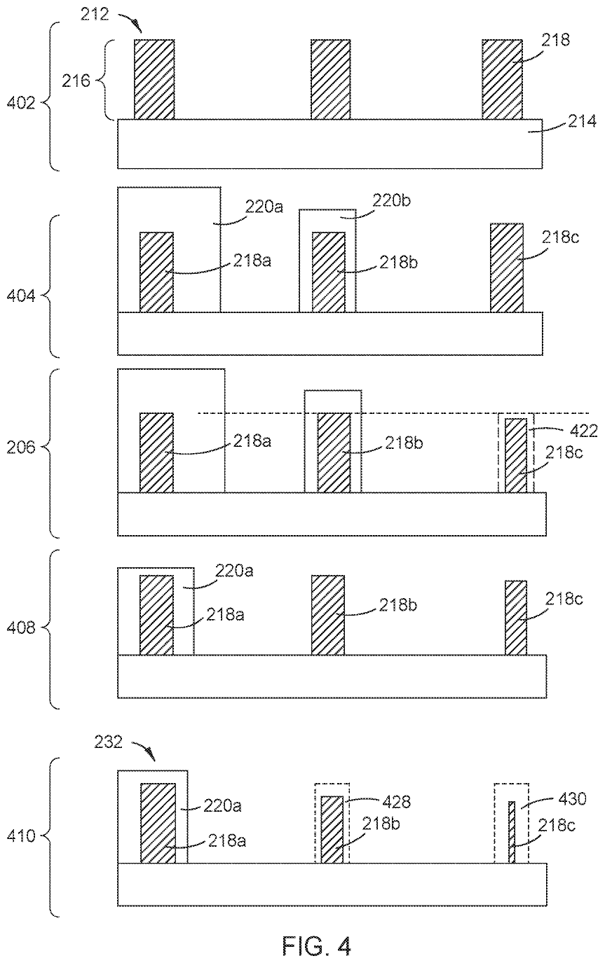

FIG. 4 is a diagram illustrating example stages 402-410 for fabricating an optical structure 432 using an isotropic etching process to reduce the height and width (or diameter) of a nanoscale structure. The reduction in the width (or diameter) may enable formation of varying duty cycle level(s) and/or further adjustment of such duty cycle levels. The same stages and/or similar stages may be performed as described herein with respect to FIG. 3. In this example, an isotropic etching process (e.g., a plasma etching process) may be performed in addition to or instead of the isotropic etching process, for example, to reduce the height and width (or diameter) of the uncovered nanoscale structure(s). In some cases, the first optical structure 212 may have nanoscale structures with larger dimensions (e.g., heights and/or widths) compared to the corresponding optical structure used in FIGS. 2 and 3 at stages 202, 302, respectively, to enable the isotropic etching.

As an example, at stage 406, an etching process may be performed to reduce a height and a width of the third nanoscale structure 218c compared to the heights and widths of the first nanoscale structure 218a and the second nanoscale structure 218b. For example, an anisotropic plasma etching process may be performed to etch at a first combination 422 of a first depth and a first critical dimension shrink (e.g., width shrink). At stage 410, an anisotropic plasma etching process may be performed to etch at a second combination 428 of a second depth and a second critical dimension shrink (e.g., width shrink), which may result in a third etch combination 430. The etching of the second nanoscale structure 218b and the third nanoscale structure 218c may form a second nanoscale structure 432 arranged in a binary pattern having levels (e.g., seven levels or more) of varying duty cycles and/or steps across a sequence of nanoscale structures as described herein with respect to FIGS. 1A and 1B.

Aspects of the present disclosure for fabricating the optical structure may use a combination of anisotropic etching as described herein with respect to FIG. 3 and isotropic etching as described herein with respect to FIG. 4.

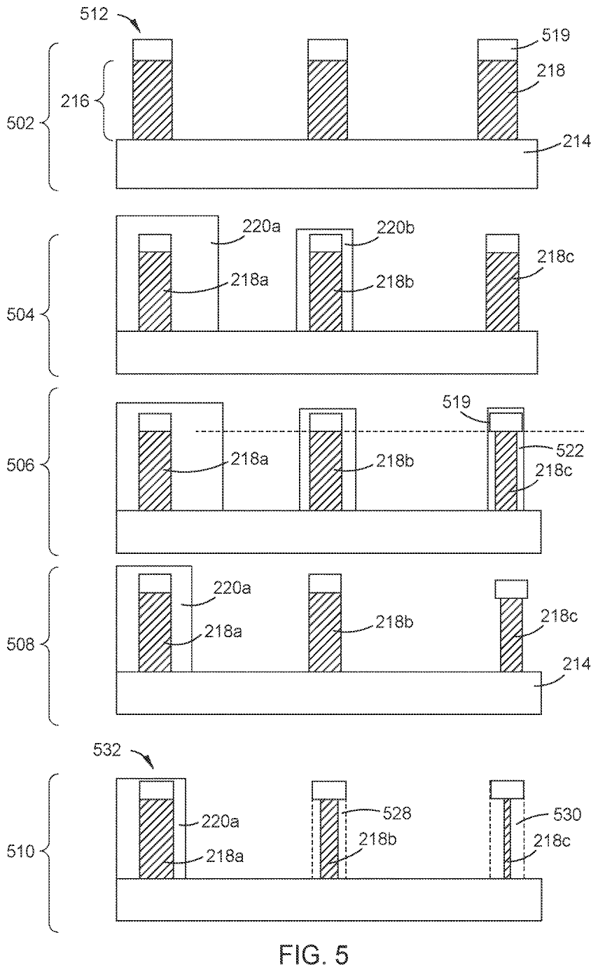

FIG. 5 is a diagram illustrating example stages 502-510 for fabricating an optical structure using a hardmask disposed above the nanoscale structures. In this example, the first optical structure 512 may include hardmask segments 519 disposed above all or some of the nanoscale structures 218. The hardmask segments 519 may be used to form the nanoscale structures 218 during an etching process (not shown). The same stages and/or similar stages may be performed as described herein with respect to FIG. 4. In this example, the hardmask segments 519 may prevent or diminish the effects of an isotropic etching process at stages 506, 510, such as preventing or diminish reduction of the height of the nanoscale structures 218b, 218c to facilitate an etch at critical dimension shrinks 522, 528, 530 (e.g., width shrinks). The etching of the second nanoscale structure 218b and the third nanoscale structure 218c may form a second nanoscale structure 532 arranged in a binary pattern having levels (e.g., seven levels or more) of varying duty cycles across a sequence of nanoscale structures as described herein with respect to FIGS. 1A and 1B.

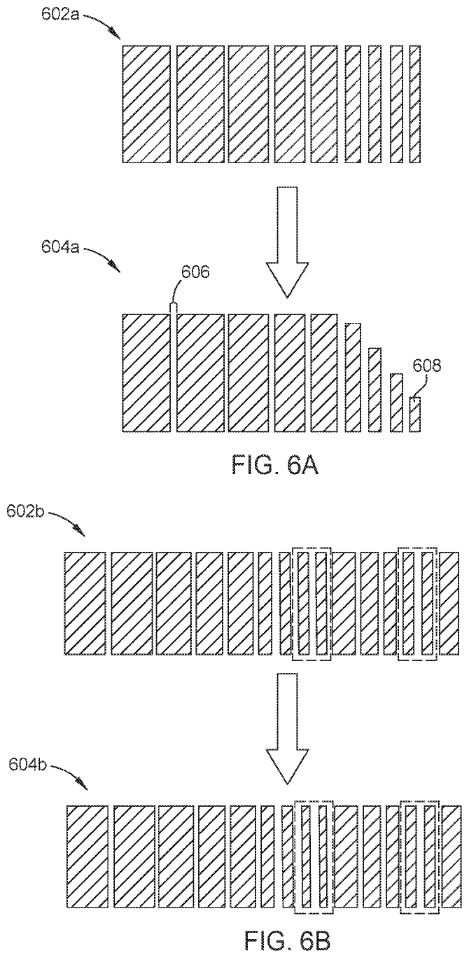

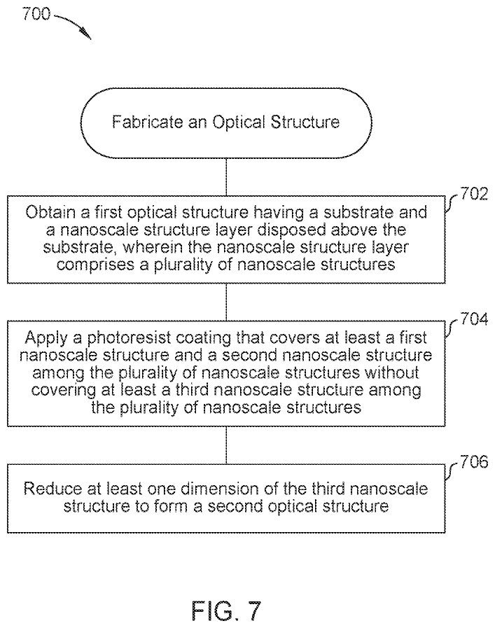

FIGS. 6A and 6B are cross-sectional views of example initial optical structures and processed optical structures associated with the methods of fabricating an optical structure described herein, for example, with respect to FIGS. 2-5. Referring to FIG. 6A, the first optical structure 602a may represent the first optical structure 212, and the second optical structure 602b may represent the second optical structure 232, 432. For example, the first optical structure 602a may have nanoscale structures arranged in a binary pattern having some varying duty cycles, for example, formed via an NTD process, and the second optical structure 604b may have the nanoscale structures arranged in a binary pattern having additional levels of varying duty cycles and levels of steps (e.g., heights) as formed via the fabrication processes described herein with respect to FIGS. 2-4. The second optical structure 604b may keep the narrow trench 606 from the first optical structure 604a, where the narrow trench 606 may be arranged between nanoscale structures for a particular duty cycle. The second optical structure 604b may be formed such that some of the nanoscale structures (e.g., the nanoscale structure 608) have a reduced height compared to the height of the respective nanoscale structure(s) of the first optical structure 602a. Such an optical structure may facilitate improved optical performance, such as a diffraction efficiency greater than 90%, for example, due to the second optical structure having seven or more levels of duty cycles and/or steps.

As shown in FIG. 6B, the first optical structure 602b may have nanoscale structures arranged in a binary pattern having some varying duty cycles, for example, formed via an NTD process. The second optical structure 604b may have the nanoscale structures arranged in a binary pattern having additional levels of varying duty cycles, for example, as formed via the fabrication process described herein with respect to FIG. 5. Here too, such an optical structure may facilitate improved optical performance, such as a diffraction efficiency greater than 90%, for example, due to the second optical structure having seven or more levels of duty cycles.

FIG. 7 is a method flow diagram illustrating example operations 700 for fabricating an optical structure, such as a photonic metasurface. The operations 700 may be performed, for example, by a photonic element fabrication system. The fabrication system may include one or more processing chambers configured to perform any of various fabrication operations, including, for example, lithography, deposition, etching, planarization, oxidation, ion implantation, and/or diffusion.

At block 702, a first optical structure (e.g., the first optical structure 212) may be obtained, where the first optical structure may include a substrate (e.g., the substrate 214) and a nanoscale structure layer (e.g., the nanoscale structure layer 216) disposed above the substrate. The nanoscale structure layer may include a plurality of nanoscale structures (e.g., the nanoscale structures 218). The nanoscale structures may include any suitable subwavelength structure, including, for example, pillars (e.g., cylindrical nanopillars), rods (e.g., nanorods), gratings (e.g., blazed grating, slanted gratings, binary gratings, etc.), lines, fins, slots, or any combinations thereof. In some aspects, a nanoscale structure may include a structure having at least one dimension (e.g., a width, radius, height, etc.) that is less than a wavelength of the operational frequency (e.g., subwavelength of light) associated with the corresponding optical device (e.g., a flat optic element or photonic metasurface). For example, the nanoscale structure may have a width, radio, and/or height that is subwavelength. In certain aspects, a nanoscale structure may include a structure that is separated from an adjacent structure by a gap or trench having a dimension that is subwavelength. Obtaining the first optical structure at block 702 may correspond to stages 202, 302, 402, 502 as described herein with respect to FIGS. 2-5, respectively.

At block 704, a photoresist coating (e.g., the photoresist coating 220) may be applied to at least some of the nanoscale structures. The photoresist coating may cover at least a first nanoscale structure (e.g., the first nanoscale structure 218a) and a second nanoscale structure (e.g., the second nanoscale structure 218b) among the plurality of nanoscale structures without covering at least a third nanoscale structure (e.g., the third nanoscale structure 218c) among the plurality of nanoscale structures. Applying and/or forming the photoresist coating (e.g., a photoresist film) may include performing a lithography process or a lithography process plus pattern transfer when multiple layers are used in the lithography process. For, example, if a trilayer process (e.g., organic planarization layer (OPL) bottom antireflection layer (BARC) and resist) is used, the resist pattern can be transferred to the OPL layer first.

At block 706, at least one dimension (e.g., a height, width, and/or diameter) of the third nanoscale structure may be reduced to form a second optical structure (e.g., the second optical structure 232). The second optical structure may include a flat optic and/or a photonic metasurface. For example, the second optical structure may include a flat lens, an optical window, a filter plate, thin-film polarizer, a diffractive optical element, or any combination thereof.

For certain aspects, the second optical structure may include the plurality of nanoscale structures arranged in a binary pattern having different nanoscale structure heights between at least two adjacent nanoscale structures (e.g., between the first nanoscale structure 218a and the second nanoscale structure 218b) among the plurality of nanoscale structures. For example, any of the anisotropic etching processes described herein with respect to FIGS. 2 and 3 and/or any of the isotropic etching process described herein with respect to FIG. 4 may be performed to facilitate the different heights among the nanoscale structures.

In certain aspects, the second optical structure may include the plurality of nanoscale structures arranged in a binary pattern (e.g., a square wave pattern) having different duty cycles (e.g., the duty cycles as described herein with respect to FIG. 1B) between at least two adjacent nanoscale structures among the plurality of nanoscale structures. For example, any of the isotropic etching processes described herein with respect to FIGS. 4 and 5 may be performed to facilitate the different duty cycles among the nanoscale structures.

For certain aspects, the second optical structure may include the plurality of nanoscale structures arranged in a binary pattern having different nanoscale structure heights and different duty cycles between at least two adjacent nanoscale structures among the plurality of nanoscale structures. For example, any of the anisotropic etching processes described herein with respect to FIGS. 2 and 3 and/or any of the isotropic etching process described herein with respect to FIGS. 4 and 5 may performed to facilitate the different duty cycles and different heights among the nanoscale structures.

In certain aspects, an etching process (e.g., a plasma etching process) may be performed to reduce (or trim) the dimension of the third nanoscale structure. To reduce the at least one dimension of the third nanoscale structure, the third nanoscale structure may be etched to reduce a width (or diameter) and/or a height of the third nanoscale structure. The third nanoscale structure may have a different width and/or different height than the first nanoscale structure.

For certain aspects, the photoresist coating may be trimmed, and an etching process may be repeated to form additional level(s) of varying duty cycles and/or steps (heights) among the nanoscale structures, for example, as described herein with respect to FIGS. 2-5. The photoresist coating may be trimmed to form a second photoresist coating that covers at least the first nanoscale structure without covering the second nanoscale structure and the third nanoscale structure. The second photoresist coating may correspond to the remaining photoresist coating 220 as depicted in stages 208, 308, 408, 508. At least one dimension of the second nanoscale structure and the third nanoscale structure may be reduced to further form the second optical structure, for example, via an etching process.

In certain aspects, the photoresist coating may be patterned into a single body that covers multiple nanoscale structures (e.g., the single body of photoresist coating 220) and/or a segmented photoresist coating (e.g., the first segment 220a and the second segment 220b), for example, as described herein with respect to FIGS. 2 and 3. For example, the photoresist coating may include a single body that coats at least the first nanoscale structure and the second nanoscale structure. In some cases, to apply the photoresist coating, the photoresist coating may be patterned to have a first segment (e.g., the first segment 220a) of the photoresist coating that covers the first nanoscale structure and a second segment (e.g., the second segment 220b) of the photoresist coating that covers the second nanoscale structure.

It will be appreciated that the methods of fabricating the optical structures described herein provide various advantages. For example, the methods of fabricating the optical structures described herein may facilitate the fabrication of an optical structure having seven or more levels of duty cycles and/or steps, which may provide improved optical performance, such as a diffraction efficiency of greater than 90%.

What is claimed is:

1. A method of fabricating an optical structure, comprising:
obtaining a first optical structure having a substrate and a nanoscale structure layer disposed above the substrate, wherein the nanoscale structure layer comprises a plurality of nanoscale structures;
applying a photoresist coating that covers at least a first nanoscale structure and a second nanoscale structure among the plurality of nanoscale structures without covering at least a third nanoscale structure among the plurality of nanoscale structures; and
reducing at least one dimension of the third nanoscale structure to form a second optical structure.

2. The method of claim 1, wherein the second optical structure comprises the plurality of nanoscale structures arranged in a binary pattern having different duty cycles between at least two adjacent nanoscale structures among the plurality of nanoscale structures.

3. The method of claim 1, wherein the second optical structure comprises the plurality of nanoscale structures arranged in a binary pattern having different nanoscale structure heights between at least two adjacent nanoscale structures among the plurality of nanoscale structures.

4. The method of claim 1, wherein the second optical structure comprises the plurality of nanoscale structures arranged in a binary pattern having different nanoscale structure heights and different duty cycles between at least two adjacent nanoscale structures among the plurality of nanoscale structures.

5. The method of claim 1, wherein reducing the at least one dimension of the third nanoscale structure comprises etching the third nanoscale structure to reduce a width of the third nanoscale structure, wherein the third nanoscale structure has a different width than the first nanoscale structure.

6. The method of claim 1, wherein reducing the at least one dimension of the third nanoscale structure comprises etching the third nanoscale structure to reduce a height of the third nanoscale structure, wherein the third nanoscale structure has a different height than the first nanoscale structure.

7. The method of claim 1, wherein reducing the at least one dimension of the third nanoscale structure comprises etching the third nanoscale structure to reduce a width and a height of the third nanoscale structure, wherein the third nanoscale structure has a different width and a different height than the first nanoscale structure.

8. The method of claim 1, further comprising:
trimming the photoresist coating to form a second photoresist coating that covers at least the first nanoscale structure without covering the second nanoscale structure and the third nanoscale structure; and
reducing at least one dimension of the second nanoscale structure and the third nanoscale structure to further form the second optical structure.

9. The method of claim 1, wherein the photoresist coating comprises a single body that coats at least the first nanoscale structure and the second nanoscale structure.

10. The method of claim 1, wherein applying the photoresist coating comprises patterning the photoresist coating to have a first segment of the photoresist coating that covers the first nanoscale structure and a second segment of the photoresist coating that covers the second nanoscale structure.

11. A method of fabricating an optical structure, comprising:
obtaining a first optical structure having a substrate and a nanoscale structure layer disposed above the substrate, wherein the nanoscale structure layer comprises a plurality of nanoscale structures;
applying a photoresist coating that covers at least a first nanoscale structure and a second nanoscale structure among the plurality of nanoscale structures without covering at least a third nanoscale structure among the plurality of nanoscale structures, wherein the photoresist coating comprises a single body that coats at least the first nanoscale structure and the second nanoscale structure; and
reducing at least one dimension of the third nanoscale structure to form a second optical structure.

12. The method of claim 11, wherein the second optical structure comprises the plurality of nanoscale structures arranged in a binary pattern having different duty cycles between at least two adjacent nanoscale structures among the plurality of nanoscale structures.

13. The method of claim 11, wherein the second optical structure comprises the plurality of nanoscale structures arranged in a binary pattern having different nanoscale structure heights between at least two adjacent nanoscale structures among the plurality of nanoscale structures.

14. The method of claim 11, wherein the second optical structure comprises the plurality of nanoscale structures arranged in a binary pattern having different nanoscale structure heights and different duty cycles between at least two adjacent nanoscale structures among the plurality of nanoscale structures.

15. The method of claim 11, wherein reducing the at least one dimension of the third nanoscale structure comprises etching the third nanoscale structure to reduce a width of the third nanoscale structure, wherein the third nanoscale structure has a different width than the first nanoscale structure.

16. The method of claim 11, wherein reducing the at least one dimension of the third nanoscale structure comprises etching the third nanoscale structure to reduce a height of the third nanoscale structure, wherein the third nanoscale structure has a different height than the first nanoscale structure.

17. The method of claim 11, wherein reducing the at least one dimension of the third nanoscale structure comprises etching the third nanoscale structure to reduce a width and a height of the third nanoscale structure, wherein the third nanoscale structure has a different width and a different height than the first nanoscale structure.

18. The method of claim 11, further comprising:
trimming the photoresist coating to form a second photoresist coating that covers at least the first nanoscale structure without covering the second nanoscale structure and the third nanoscale structure; and
reducing at least one dimension of the second nanoscale structure and the third nanoscale structure to further form the second optical structure.

19. A method of fabricating an optical structure, comprising:
obtaining a first optical structure having a substrate and a nanoscale structure layer disposed above the substrate, wherein the nanoscale structure layer comprises a plurality of nanoscale structures;
applying a photoresist coating that covers at least a first nanoscale structure and a second nanoscale structure among the plurality of nanoscale structures without covering at least a third nanoscale structure among the plurality of nanoscale structures, wherein the photoresist coating comprises a single body that coats at least the first nanoscale structure and the second nanoscale structure; and
reducing at least one dimension of the third nanoscale structure to form a second optical structure by etching the third nanoscale structure to reduce a width of the third nanoscale structure, wherein the third nanoscale structure has a different width than the first nanoscale structure.

20. The method of claim 19, wherein reducing the at least one dimension of the third nanoscale structure further comprises etching the third nanoscale structure to reduce a height of the third nanoscale structure, wherein the third nanoscale structure has a different height than the first nanoscale structure.
